(19) United States
(12) Patent Application Publication
(10) Pub. No.: US 2013/0309856 A1
(43) Pub. Date: Nov. 21, 2013

(54) ETCH RESISTANT BARRIER FOR REPLACEMENT GATE INTEGRATION

(71) Applicants: HEMANTH JAGANNATHAN, GUILDERLAND, NY (US); SANJAY MEHTA, NISKAYUNA, NY (US); CHUN-CHEN YEH, CLIFTON PARK, NY (US)

(72) Inventors: HEMANTH JAGANNATHAN, GUILDERLAND, NY (US); SANJAY MEHTA, NISKAYUNA, NY (US); CHUN-CHEN YEH, CLIFTON PARK, NY (US)

(73) Assignee: INTERNATIONAL BUSINESS MACHINES CORPORATION, ARMONK, NY (US)

(21) Appl. No.: 13/471,980

(22) Filed: May 15, 2012

(51) Int. Cl. H01L 21/28

(52) U.S. Cl. 438/587; 257/E21.19

(57) ABSTRACT

Semiconductor devices and methods of their fabrication are disclosed. One method includes forming a semiconductor device structure including a plurality of dummy gates and a dielectric gap filling material with a pre-determined aspect ratio that is between the dummy gates. An etch resistant nitride layer is applied above the dielectric gap filling material to maintain the aspect ratio of the gap filling material. In addition, the dummy gates are removed by implementing an etching process. Further, replacement gates are formed in regions of the device structure previously occupied by the dummy gates.

### BACKGROUND

1. Technical Field

The present invention relates to semiconductor devices, and more particularly to barriers employed in the fabrication of semiconductor devices.

2. Description of the Related Art

Integration of complementary metal-oxide-semiconductor (CMOS) devices at the 22 nm node and beyond presents several important challenges. For example, due to the small scale of the devices and the three-dimensional configuration of finFET and Trigate devices, a high aspect ratio gap filling layer should be applied between the gates during fabrication prior to performing contact etching. With regard to replacement metal gate schemes in particular, in addition to providing a defect-free gap fill and a relative ease of application, this gap filling layer should exhibit very good wet etch resistance properties.

During fabrication of a CMOS device, a gap filling layer can be formed by implementing spin-on glass (SOG) techniques or Chemical Vapor Deposition (CVD) of flowable oxide. Further, planarization of the resulting oxide can be performed such that it stops on top of the gate hard mask (HM) of the CMOS device structure. Although the oxide is relatively easy to apply in this way, the oxide has a very poor wet etch resistance due to the restricted thermal budget it imposes. To address this problem, the oxide can be recessed and filled with an etch resistant capping material, such as high density plasma (HDP) deposited Oxide, to minimize excessive loss during the dummy gate pull and high k pre-clean stages, which can otherwise cause shorts between the gate and the source or drain of the device. Alternatively, in replacement metal gate (RMG) fabrication schemes, to prevent shorts, the dummy gate stack height can be increased to provide a sufficient margin to remove work function (WF) and gate metals in the recess by chemical mechanical planarization (CMP) overpolishing. This scheme can be challenging due to the high aspect ratios of high-k metal gates (HKMGs) in finFET and Trigate device geometries.

### SUMMARY

One illustrative embodiment is directed to method for fabricating a semiconductor device. The method includes constructing a semiconductor device structure including a plurality of dummy gates and dielectric gap filling material that has a pre-determined aspect ratio and that is between the dummy gates. An etch resistant nitride layer is formed above the dielectric gap filling material to maintain the aspect ratio of the gap filling material. In addition, the dummy gates are removed by implementing an etching process. Further, replacement gates are formed in regions of the device structure previously occupied by the dummy gates.

An alternative embodiment is also directed to a method for fabricating a semiconductor device. The method includes constructing a semiconductor device structure including a plurality of dummy gates and a first gap filling layer that is composed of a dielectric material. The first gap filling layer has a pre-determined aspect ratio and is disposed between the dummy gates. A nitride layer is formed above the first gap filling layer to maintain the aspect ratio of the first gap filling layer. A second gap filling layer, which is composed of the dielectric material, is formed over the nitride layer and between the dummy gates. The dummy gates are removed by implementing an etching process. Further, replacement gates are formed in regions of the device structure previously occupied by the dummy gates.

Another embodiment is directed to a multigate transistor device. The method includes constructing a semiconductor device structure including a plurality of dummy gates, a plurality of fins and a first gap filling layer that is composed of a dielectric material, is between the dummy gates and has a pre-determined aspect ratio. An etch resistant nitride layer is formed over the first gap filling layer to maintain the aspect ratio of the first gap filling layer. Further, a second gap filling layer, which is composed of the dielectric material, is formed over the nitride layer and between the dummy gates. The dummy gates are removed by implementing an etching process. In addition, replacement gates are formed in regions of the device structure previously occupied by the dummy gates.

An alternative embodiment is directed to a semiconductor device. The device includes a plurality of gates, a dielectric gap filling material and an etch resistant nitride layer. The dielectric gap filling material is disposed between the gates and has a pre-determined aspect ratio. In addition, the nitride layer is configured to maintain the aspect ratio of the dielectric gap filling material during fabrication of the device and is disposed above the dielectric gap filling material and between the plurality of gates.

Another embodiment is also directed to a semiconductor device. The device includes a plurality of gates, a dielectric gap filling material and a nitride layer. The dielectric gap filling material has a pre-determined aspect ratio. Further, the nitride layer is disposed above the dielectric gap filling material and between the plurality of gates. Moreover, the nitride layer is configured to maintain the aspect ratio of the dielectric gap filling material during fabrication of the device. In addition, the nitride layer acts as an island, where the gates are separated by the nitride layer.

An alternative embodiment is directed to a multigate transistor device. The device includes a plurality of gates, a plurality of fins beneath the gates and a dielectric gap filling material. The dielectric gap filling material is between the gates and has a pre-determined aspect ratio. The device further includes an etch resistant nitride layer that is configured to maintain the aspect ratio of the dielectric gap filling material during fabrication of the device and is disposed above the dielectric gap filling material and between the plurality of gates.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a cross-sectional view of a wafer employed in the fabrication of a semiconductor device in accordance with an exemplary embodiment;

FIG. 2 is a cross-sectional view of a semiconductor device structure illustrating a gap fill deposition stage in accordance with an exemplary embodiment;

FIG. 3 is a cross-sectional view of a semiconductor device structure illustrating the implementation of Chemical Mechanical Planarization on the surface of the device structure of FIG. 2 in accordance with an exemplary embodiment;

FIG. 4 is a cross-sectional view of a semiconductor device structure illustrating a recessing step implemented to form an inter-gate capping layer in accordance with an exemplary embodiment;

FIG. 5 is a cross-sectional view of a semiconductor device structure illustrating the formation of an etch resistant nitride layer configured to maintain the aspect ratio of the inter-gate gap fill material in accordance with an exemplary embodiment;

FIG. 6 is a cross-sectional view of a semiconductor device structure illustrating an additional gap filling stage in accordance with an exemplary embodiment;

FIG. 7 is a cross-sectional view of a semiconductor device structure illustrating an additional planarization stage in accordance with an exemplary embodiment;

FIG. 8 is a cross-sectional view of a semiconductor device structure illustrating the removal of caps of dummy gates in accordance with an exemplary embodiment;

FIG. 9 is a cross-sectional view of a semiconductor device structure illustrating a Dummy Gate Removal in accordance with an exemplary embodiment;

FIG. 10 is a cross-sectional view of a semiconductor device structure illustrating a replacement gate filling stage in accordance with an exemplary embodiment;

FIG. 11 is a cross-sectional view of a semiconductor device structure illustrating a planarization step that selectively stops on top of the dielectric filling material between gates in accordance with an exemplary embodiment;

FIG. 12 is a cross-sectional view of a semiconductor device illustrating a planarization step that selectively stops on top of the nitride capping layer between gates in accordance with an exemplary embodiment;

FIG. 13 is a cross-sectional view of an integrated semiconductor device fabricated in accordance with an exemplary embodiment;

FIG. 14 is a cross-sectional view of an integrated semiconductor device fabricated in accordance with an alternative exemplary embodiment; and

FIG. 15 is a block/flow diagram of an exemplary method for fabricating a semiconductor device in accordance with exemplary embodiments.

### DETAILED DESCRIPTION OF PREFERRED EMBODIMENTS

Embodiments of the present principles are directed to facilitating the fabrication of CMOS devices. For example, the embodiments described herein provide substantial advantages and benefits for replacement metal gate fabrication schemes. As noted above, if RMG schemes are employed to fabricate small scale devices, a gap filling layer that has a high aspect ratio and exhibits wet etch resistance properties as well ease of application should be applied between the gates prior to performing contact etching.

As also noted above, one method of fabricating CMOS devices caps the gap fill oxide with an HDP process. However, this approach has several disadvantages. For example, the aspect ratio of the gap fill layer is limited to 4:1, beyond which it is increasingly difficult to maintain a gap fill material that is free of defects using HDP. Even at the 4:1 aspect ratio, the gap filling process requires a large number deposition and etch cycles when HDP is employed. The large number of etch cycles poses problems, as etch cycles could potentially cause corner erosion of the hard mask (HM) material on top of the gate. Further, the HM erosion reduces the reliability of stopping on the nitride layer during CMP of the HDP oxide. Moreover, when HDP is used, it is generally difficult to achieve a defect-free gap fill in very narrow spaces in the tight pitch macros. As such, a defective HDP cap poses an increased risk of exposure to the wet etch chemistry, which may cause an excessive etching and loss of the underlying oxide during the gate pull and high k pre-clean stages and, as a result, may cause shorts. The recess depth, and hence cap thickness, below a SiN Cap is dependent on the etch rate of the HDP capping gate oxide and the total wet etch budget for gate pulling and HKMG pre-cleaning stages.

Embodiments of the present principles avoid the problems associated with employing a high etch budget for a middle of the line (MOL) (i.e., contact level) oxide. In particular, the inventors have found that certain types of wet etch resistant films permit the formation of a gap filling layer between gates during fabrication that have a high aspect ratio. In addition, the film permits a significant degree of latitude with regard to the top capping oxide employed in the structure. For example, the top oxide need not be etch resistant and can be sacrificial. Thus, this oxide can be the same or similar to the one used for the gap fill material, such Spin-on Dielectric (SOD) or flowable CVD oxides.

In accordance with one embodiment, a wet etch resistant thin conformal barrier nitride film can be applied in the recess formed by etching of the planarized gap fill oxide. For example, the thickness of the wet etch resistant film can be between about 50 Å-150 Å and the film can be composed of, for example, SiN, SiCN or SiBCN. The film can be deposited using any one or more of plasma enhanced atomic layer deposition (PEALD), Thermal atomic layer deposition (ALD), or cyclic plasma enhanced CVD (PECVD) processes. The remaining portion of the recess can be filled using any gap fill oxide, including but not limited to SOD or CVD oxides. This is followed by CMP. Subsequently the gate hard mask is removed, followed by a polysilicon dummy gate etch and high-k (HK) pre-clean stages that would remove any excess native oxide on top of what is to become a semiconductor, e.g., silicon, channel inside the dummy gate mold prior to high-k/work function metal deposition. This gate pre-clean chemistry is often incompatible with the MOL oxide HDP. However, the presence of a barrier cap, such as a SiBCN cap, essentially prevents etching of the flowable oxide gap fill material. The etch-resistant barrier cap prevents any loss of the gap fill oxide by protecting the high etch-rate oxide during a pre-cleaning stage prior to high-k dielectric deposition. This is followed by the HK material deposition, WF metal deposition and gate filling, where the gate fill material can be deposited over the residual oxide on top of the nitride film and subsequently removed during CMP. The conformal nature of this cap protects the underlying gap fill MOL oxide.

It should be understood that aspects of the present invention are described below with reference to flowchart illustrations and/or block diagrams of methods, apparatus (systems) and computer program products according to embodiments of the invention.

The flowchart and block diagrams in the Figures illustrate the architecture, functionality, and operation of possible implementations of systems, methods and devices according to various embodiments of the present invention. It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It is to be understood that the present invention will be described in terms of a given illustrative architecture having a substrate; however, other architectures, structures, substrate materials and process features and steps may be varied within the scope of the present invention.

It will also be understood that when an element described as a layer, region or substrate is referred to as being “on” or “over” another element, it can be directly on the other element or intervening elements may also be present. In contrast, when an element is referred to as being “directly on” or “directly over” another element, there are no intervening elements present. Similarly, it will also be understood that when an element described as a layer, region or substrate is referred to as being “beneath” or “below” another element, it can be directly beneath the other element or intervening elements may also be present. In contrast, when an element is referred to as being “directly beneath” or “directly below” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A design for an integrated circuit chip or chips in accordance with the principles described herein may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format and may include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

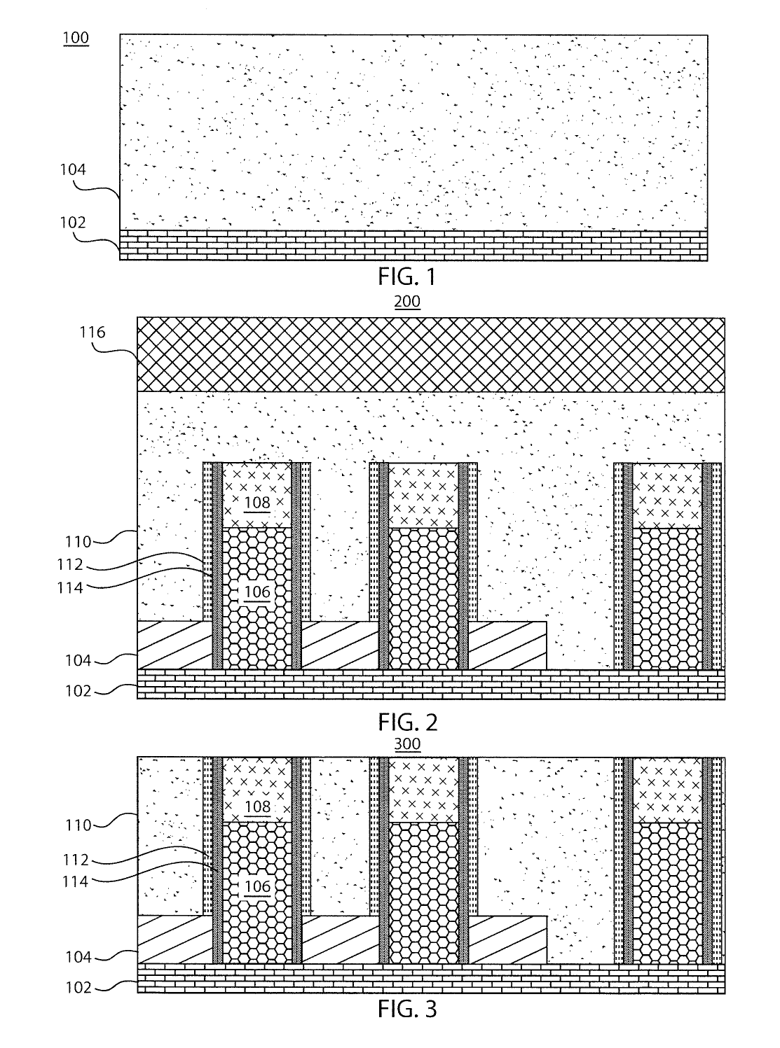

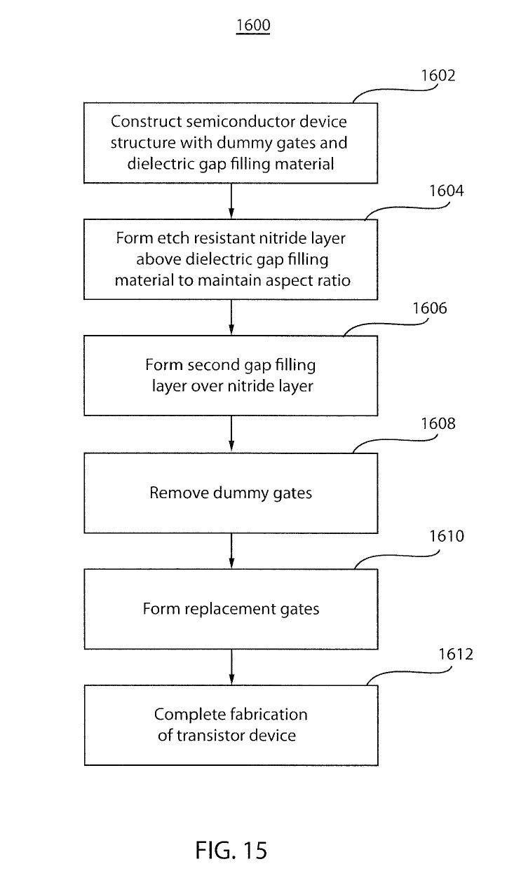

Referring now to the drawings in which like numerals represent the same or similar elements, processes for fabricating a semiconductor device in accordance with exemplary embodiments are illustratively depicted. In particular, FIGS. 1-14 illustrate semiconductor device structures during various processing stages of fabrication. In addition, FIG. 15 is a high-level block/flow diagram of a method 1600 for fabricating the semiconductor device. The device structures of FIGS. 1-14 and the method block/flow diagram of FIG. 15 are referenced concurrently in the description provided herein below to facilitate ease of understanding.

The fabrication method 1600 can begin at step 1602, at which a semiconductor device structure can be constructed. For example, as illustrated in FIGS. 1 and 2, a silicon on insulator (SOI) substrate 100, including a silicon layer 104 and a buried oxide layer (BOX) 102, can be processed to form the structure 200 of FIG. 2. It should be noted that various other substrates can be used, such as a bulk silicon substrate, in accordance with alternative embodiments. Here, the structure 200 can include a plurality of dummy gate structures including dummy gates 106, caps 108, and spacers 112 and 114. The caps 108 can be composed of SiN. Dummy gate 106 materials include, but are not limited to, any one or more of amorphous or polycrystalline Si, SiO₂, SiON, SiGe, Ge, GeO₂, amorphous C, BC, CN, etc. The capping materials could include any one or more of SiN, SiCN, SiBN and/or SiBCN, among other materials. Further, the inner 114 and outer spacers 112 could be composed of any one or more of SiN, SiBN, SiCN and/or SiBCN films.

In addition, the structure 200 can also include epitaxial layers 104. Epitaxial layers could be of the same or different materials for on pFET and nFET devices, and could be either in-situ doped with appropriate polarity dopants (B for pFET and P for nFET devices) or left un-doped. Although not illustrated in this particular figure, it should be noted that the semiconductor device can be a multigate transistor device, such as a finFET device or a trigate device, where the fins are disposed beneath the dummy gates 106. Thus, the epitaxial layers 104 can be grown around fins, which can be source or drain regions of the device. The fins can be partially or wholly formed of the silicon of the substrate, as understood by those of ordinary skill in the art. It should be noted that the structure composed of elements 102, 104, 106, 108, 112, 114 and 116 can be formed in accordance with known methods, as understood by those of ordinary skill in the art.

The gaps between the dummy gate structures can be filled by depositing a dielectric material 110 in the gaps. For example, the dielectric material 110 can be composed of a flowable oxide. For example, the dielectric material can be SiO₂, or C-doped Silicon Oxide, and can be formed via any of a variety of techniques, such as PECVD, sub-atmospheric chemical vapor deposition (SACVD), HDP or spin on glass coating. The CVD of SiO₂ may include processes that use oxidation of a highly reactive amine-based precursor to form short chain polymer molecules that possess re-flow properties to conform to the gap independently of the gap geometry. Such films would involve oxidative anneals in the range of 300° C. to 600° C. to achieve densification via cross-linking of the Si—O—Si network. The spin coating chemistry could be polysiloxane or polysilazane based and would involve curing and/or steam oxidation to hydrolyze terminal bonds for condensation to form a dense network of Si—O—Si.

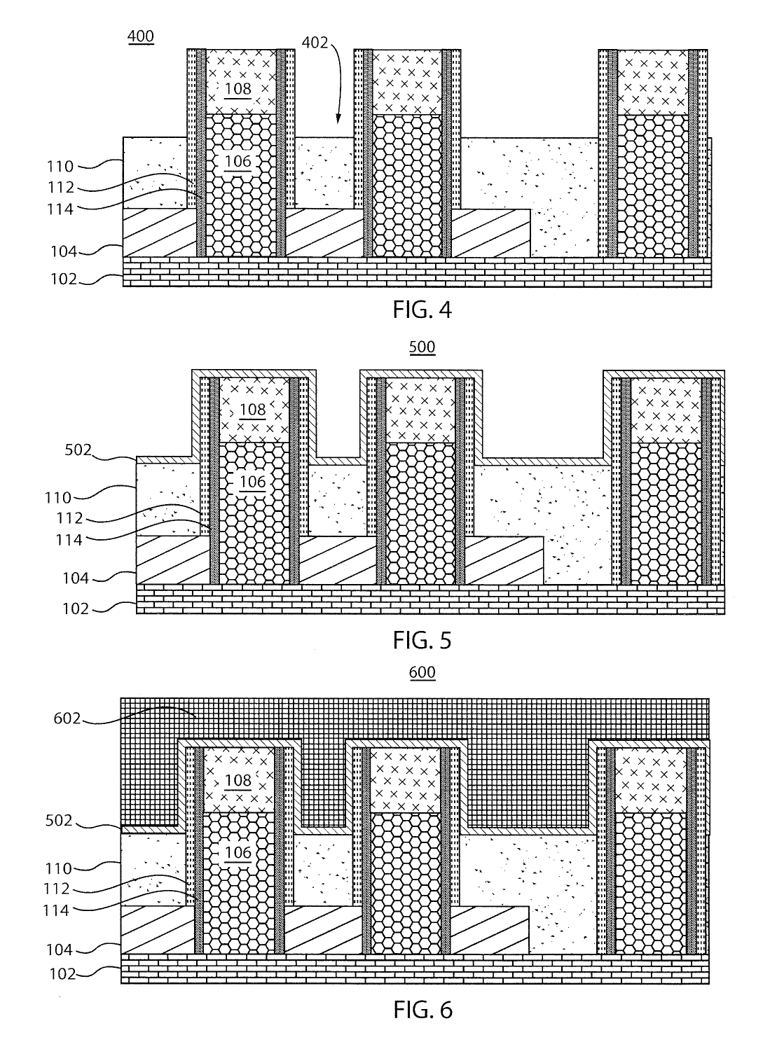

In addition, a sacrificial PECVD SiO₂ layer 116 can optionally be deposited using either a TEOS (Tetra Ethyl Ortho Silicate) or a Silane (SiH₄) precursor over the dielectric material or layer 110 to provide an additional overburden for the subsequent CMP step. Thereafter, as illustrated in structure 300 in FIG. 3, layer 116 and the dielectric material 110 above the caps 108 are removed by performing Chemical Mechanical Planarization using a SiN selective slurry. Here, the CMP stops on the hard mask 108. As shown in structure 400 of FIG. 4, the dielectric material 110 is subsequently planarized and recesses 402 are formed using either a dry etch, such as advanced isotropic dry cleaning, for example SICONI (in situ pre Ni silicide) cleaning or COR (chemical oxide removal), or a wet etch, which may, for example, employ HF-based chemistries. It should be noted that the depth of the recesses can be controlled such that the recess is at least 150-200 Å from the bottom of the gate cap layer 108. Thus, the height of Gate hard mask 108 and the recess depth of the gap fill oxide below the hard mask 108 together with lateral dimensions of the gap fill space determine the aspect ratio for the etch resistant nitride cap material deposition described below. Here, the depth of the recesses can be controlled so that the dielectric material 110 between the gates 106 have a predetermined aspect ratio. As noted above, for small scale devices, a high aspect ratio gap filling layer between the gates can be obtained during fabrication prior to performing contact etching. The aspect ratio of the gap filling material 110 here should be between about 6 and 10.

At step 1604, a wet etch resistant, conformal nitride layer 502 can be deposited above the dielectric gap filling material, as, for example, shown in structure 500 in FIG. 5, to maintain the aspect ratio of the gap filling material. Here, the barrier nitride layer is a conformal wet etch resistant nitride layer that is deposited in the recesses formed after gap fill oxide planarization in this example. The nitride layer can be a silicon nitride layer and, in particular, can be SiCN and/or SiBCN, which can be deposited using at least one of a PEALD process, a thermal ALD process or a PECVD process, among other deposition processes. As indicated above, an advantage of this methodology is that the nitride film enables the use of a recess depth that is significantly reduced due to high wet/dry etch selectivity of this film over the case in which only an HDP oxide cap is used, and provides additional etch protection to the underlying gap fill oxide. For example, nitride films such as SiCN and/or SiBCN films remain un-etched in the presence of HF, Hot Ammonium Hydroxide Huang A (SC1) or Huang B (SC2), and Isotropic and Dry Oxide Etch Processes, such as SICONI or COR.

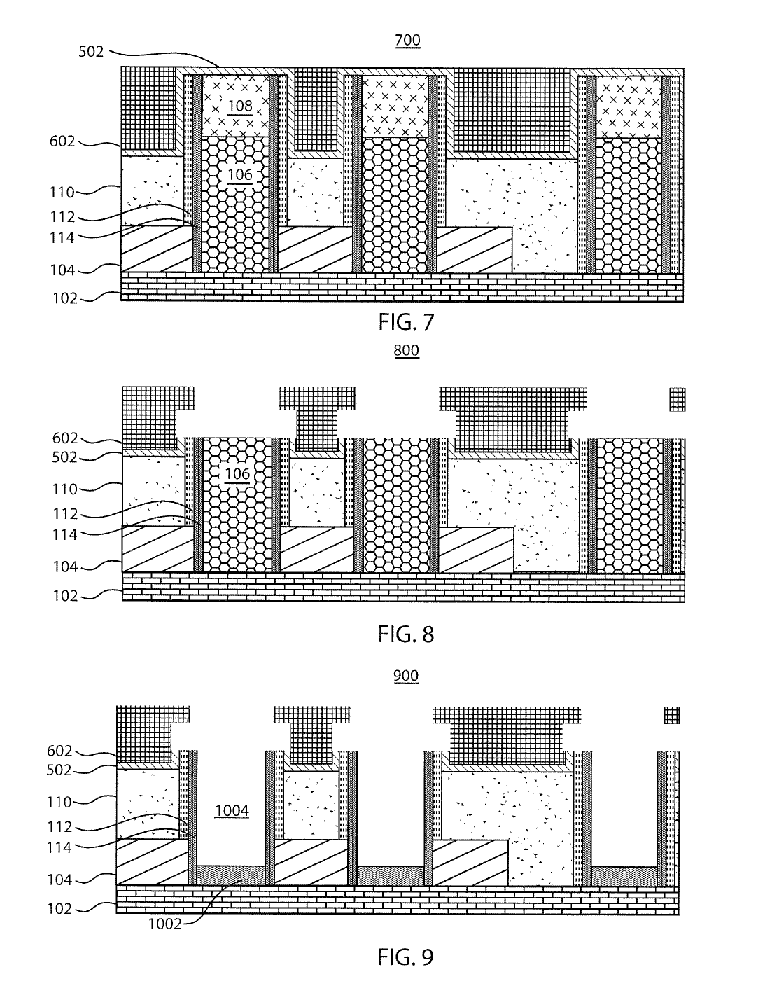

At step 1606, a second dielectric gap filling material can be formed directly over the nitride layer 502 and between the dummy gates 106, for example, as illustrated in structures 600 and 700 of FIGS. 6 and 7, respectively. The second dielectric layer 602 can be composed of any gap fill oxide, including SOD or CVD oxide. Indeed, to simply the fabrication process and enhance the efficiency of the fabrication of the semiconductor device, dielectric layers 602 and 110 can be composed of the same material and formed using the same or similar processes. This feature is in sharp contrast with the HDP fabrication method described above. As illustrated in FIG. 7, the material 602 can be planarized in accordance with CMP. In addition, the planarization can be configured to stop on the etch resistant layer 502, as shown in FIG. 7. Dummy gate 106 etch and high-K pre-clean chemistries could potentially etch any oxide above this etch resistant layer 502 and could expose the etch resistant capping layer 502 above the dummy gates. The etch resistant layer 502 prevents any further loss of the gap fill material.

At step 1608, the nitride cap above the dummy gate and the dummy gates can be removed by implementing an anisotropic Reactive Ion Etch (RIE) process and/or a wet etching process, for example, as shown in structures 800 and 900 in FIGS. 8 and 9, respectively. Here, as illustrated in FIG. 8, the nitride layer 502 above the dummy gates 106 is etched, along with the layers 112 and 114 and caps 108 above the dummy gates 106. Of course the etching is selective with respect to the dielectric material 602. The gate hard mask layer 108 can be removed using reactive ion etching that is selective to the dielectric layer 602. Subsequently, as shown by structure 900 in FIG. 9, the dummy gates 106 can be removed. For example, if the dummy gate 106 is made of amorphous or poly-Si, it can be etched in hot NH₄OH or Tetra. Methyl Ammonium Hydroxide (TMAH) chemistries in a manner that is selective to the dielectric layer 602. For example, native SiO₂ around the portion of Si Fin inside the gate mold should be removed prior to deposition of a High k Dielectric using HF based wet chemistries. HF chemistries are not selective and result in etching of oxide material above the cap 502. As illustrated in FIG. 9, the removal of the dummy gate exposes the fins 1002 of a multigate device in this exemplary embodiment.

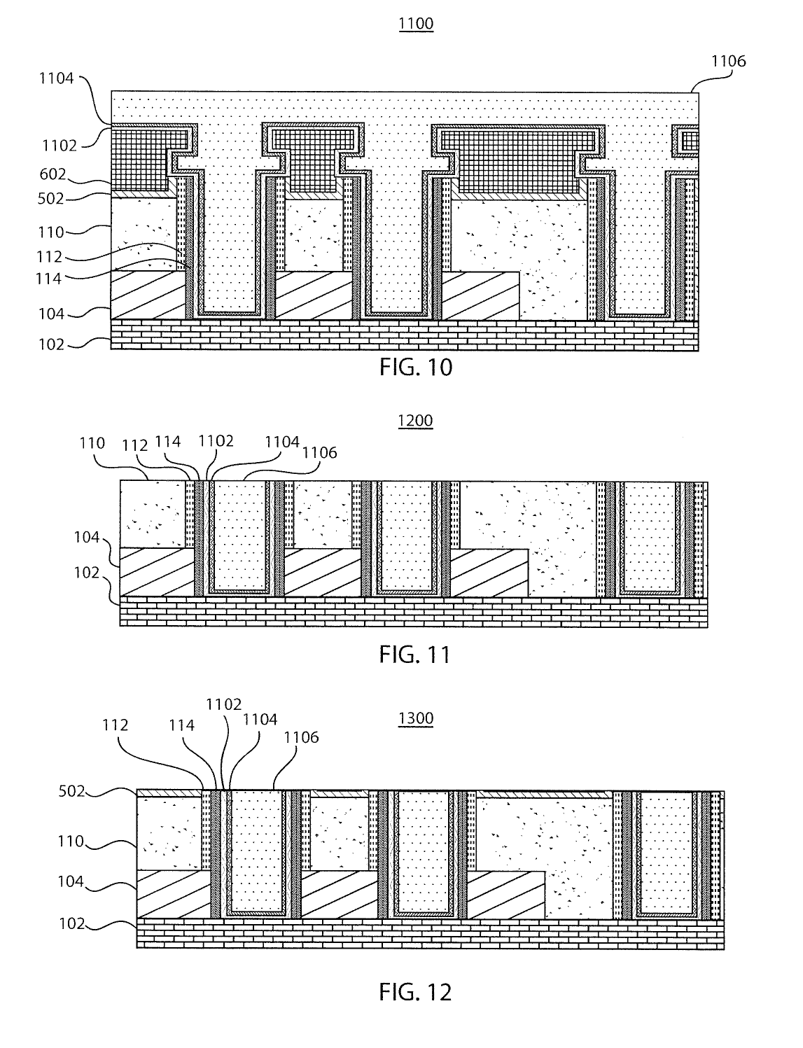

At step 1610, replacement gates 1106 are formed in regions 1004 of the device structure previously occupied by the dummy gates 106, for example, as shown in structures 1100, 1200 and 1300 in FIGS. 10-12, respectively. For example, a high-k material 1102 and a work function metal 1104 can be deposited, followed by deposition of a gate filling material 1106. The gate material 1106 can be any of the materials HfO_{X}, HfSiOₓ, Al₂O₃, ZrO₂, ZrSiOₓ, among other materials. The work function material can include any of the following metal compounds TiN, TaN, TiC, TaC, La₂O₃, Al, AlOₓ, among other materials. Both high-k and work function metals can be deposited by PVD, CVD or ALD processes. ALD processes are preferred for finFET/Trigate devices due to the superior lateral step coverage they offer. Thereafter, the conductive electrode for the replacement gates is deposited. The conductive electrode can be W or Al and can be deposited via PECVD or PVD techniques. Here, if a multigate device is fabricated in accordance with the method 1600, then the replacement gates are formed over fins 1002. Thereafter, the etch resistant nitride 502 as well as excess gate filler 1106 can be removed by performing CMP, as illustrated in FIG. 11. The conformal nature of the nitride 502 protects the dielectric material 110. In accordance with an alternative embodiment, at least a portion of the nitride layer can remain in the device. For example, as illustrated in FIG. 12, the etch resistant material 502 can be configured as islands between the gates such that the gates are separated by the nitride capping layers. Here, CMP can be performed over the gate fill conductive materials 1102, 1104 and 1106 to remove the etch resistant cap 502 on the field regions. The etch resistant material 502 can remain to act as a barrier and to protect the underlying material 110 and 104 from other processes performed to fabricate a larger integrated circuit in which the semiconductor device 1300 is implemented.

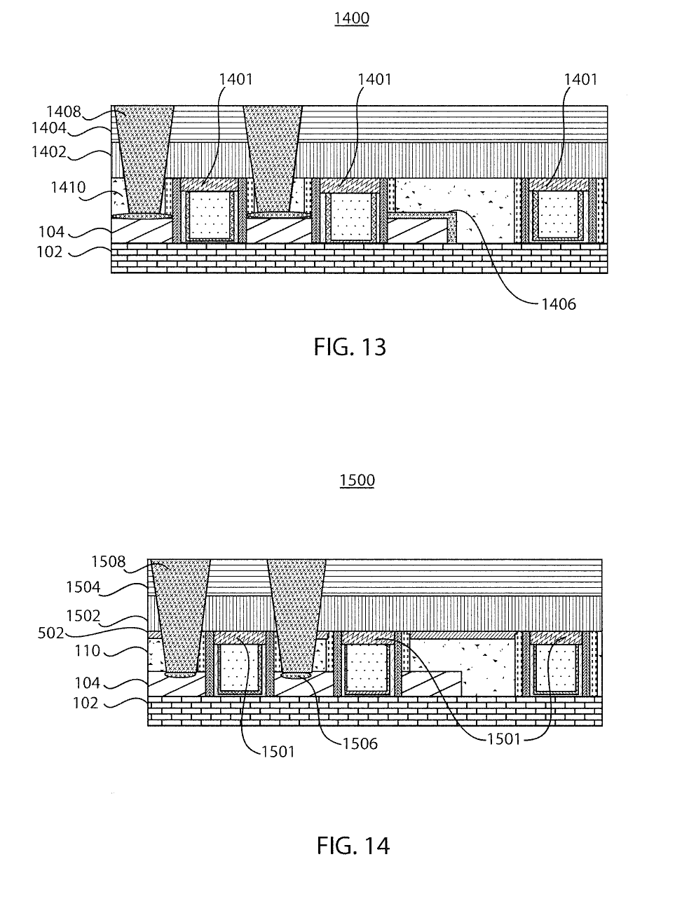

At step 1612, the fabrication of the semiconductor device can be completed. For example, structure 1400 of FIG. 13 can be formed using the structure 1200 of FIG. 11 in which the barrier layer 502 has been removed. For example, in accordance with a self-aligned contact (SAC) scheme at a sub-70 nm gate pitch, the gate electrode 1106 can be recessed, a dielectric cap 1401 can be formed over the gate electrode and chemical-mechanical planarization can be performed. The dielectric cap 1401 can prevent shorting from mislanded source/drain contacts subsequently formed. In addition, a conventional self-aligned silicide (salicide) formation process can be implemented. For example, the dielectric gap fill material 110 can be stripped and silicide 1406 can be formed over the exposed semiconductor layers 104 in source/drain regions to form contacts 1408. Further, a dielectric material 1410 can be formed over the silicide 1406 and semiconductor layers 104 in the source/drain regions and can be planarized to stop on the dielectric cap above the replacement (or dummy) gate. Subsequently, barrier layer 1402, which can be composed of a nitride material, and a dielectric layer 1404, which can be an oxide, can be formed over the sample surface, as shown in FIG. 13.

In an alternative implementation, structure 1500 of FIG. 14 can be formed using the structure 1300 of FIG. 12, in which portions of the nitride layer 502 remain in the final structure. For example, similar to the structure 1400, the gate electrode 1106 can be recessed, a dielectric cap 1501 can be formed over the gate electrode and chemical-mechanical planarization can be performed. As indicated above, the dielectric cap 1501 can prevent shorting from mislanded source/drain contacts subsequently formed. Here, as opposed to removing the dielectric layer 110 and performing salicidation, at least a portion of the dielectric layer 110 is retained and trench salicidation is performed post-contact patterning at the end of the process. For example, after capping the gate structures with cap 1501, a barrier layer 1502, which can be a nitride, and a dielectric layer 1504, which can be an oxide, are formed over the sample surface. Trench contacts 1506 are formed through the layers 1401 and 1402 to land in the source/drain regions. Salicidation is then performed through contacts at the trench bottom to form contacts 1508.

The advantage of the methodologies described herein is that the recess depth can be significantly reduced due to high wet/dry etch selectivity of the barrier film over HDP oxides. In particular, the barrier film is virtually un-etched in HF, Hot ammonia, Huang A (SC1), Huang B (SC2), SiCONI or COR.

Having described preferred embodiments of devices including an etch resistant barrier for replacement gate integration, and methods of their fabrication, (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A method for fabricating a semiconductor device comprising:
constructing a semiconductor device structure including a plurality of dummy gates and dielectric gap filling material that has a pre-determined aspect ratio and that is between the dummy gates;
forming an etch resistant nitride layer above the dielectric gap filling material to maintain the aspect ratio of the gap filling material;
removing the dummy gates by implementing an etching process, wherein the etch resistant nitride layer entirely covers said dielectric gap filling material between the dummy gates during said removing; and
forming replacement gates in regions of the device structure previously occupied by the dummy gates.

2. The method of claim 1, wherein the dielectric gap filling material is a first dielectric gap filling material and wherein the method further comprises:
forming a second dielectric gap filling material over the nitride layer and between the dummy gates.

3. The method of claim 2, wherein the first dielectric gap filling material and the second dielectric gap filling material are composed of the same material.

4. The method of claim 3, wherein the first and second dielectric gap filling material is a flowable plasma-enhanced chemical vapor deposition (PECVD) oxide, sub-atmospheric chemical vapor deposition (SACVD) oxide, high density plasma (HDP) oxide or spin-on-glass (SOG) oxide.

5. The method of claim 1, wherein the nitride layer is composed of at least one of SiCN or SiBCN and wherein the forming the etch resistant nitride layer further comprises implementing at least one of a plasma-enhanced atomic layer deposition (PEALD) process, a thermal atomic layer deposition (ALD) process or a cyclic plasma-enhanced chemical vapor (PECVD) process.

6. The method of claim 1, wherein the forming replacement gates further comprises removing the nitride layer.

7. The method of claim 1, wherein the method further comprises:
completing the formation of the semiconductor device such that at least a portion of the nitride layer remains in the device.

8. The method of claim 1, wherein the etching process is a wet etching process and the nitride layer is wet etch resistant.

9. The method of claim 1, wherein the aspect ratio is between 6 and 10.

10. A method for fabricating a semiconductor device comprising:
constructing a semiconductor device structure including a plurality of dummy gates and a first gap filling layer that is composed of a dielectric material, is between the dummy gates and has a pre-determined aspect ratio;
forming a nitride layer above the first gap filling layer to maintain the aspect ratio of the first gap filling layer;
forming a second gap filling layer, which is composed of the dielectric material, over the nitride layer and between the dummy gates;
removing the dummy gates by implementing an etching process, wherein the nitride layer entirely covers said dielectric material of said first gap filling layer between the dummy gates during said removing; and
forming replacement gates in regions of the device structure previously occupied by the dummy gates.

11. The method of claim 10, wherein the dielectric material is a flowable plasma-enhanced chemical vapor deposition (PECVD) oxide, sub-atmospheric chemical vapor deposition (SACVD) oxide, high density plasma (HDP) oxide or spin-on-glass (SOG) oxide.

12. The method of claim 10, wherein the nitride layer is composed of at least one of SiCN or SiBCN and wherein the forming the nitride layer further comprises implementing at least one of a plasma-enhanced atomic layer deposition (PEALD) process, a thermal atomic layer deposition (ALD) process or a cyclic plasma-enhanced chemical vapor (PECVD) process.

13. The method of claim 10, wherein the forming replacement gates further comprises removing the nitride layer.

14. The method of claim 10, wherein the method further comprises:
completing the formation of the semiconductor device such that at least a portion of the nitride layer remains in the device.

15. The method of claim 10, wherein the forming replacement gates further comprises forming the replacement gates over fins.

16. The method of claim 10, wherein the aspect ratio is between 6 and 10.

17. A method for fabricating a multigate transistor device comprising:
constructing a semiconductor device structure including a plurality of dummy gates, a plurality of fins and a first gap filling layer that is composed of a dielectric material, is between the dummy gates and has a pre-determined aspect ratio;
forming an etch resistant nitride layer over the first gap filling layer to maintain the aspect ratio of the first gap filling layer;
forming a second gap filling layer, which is composed of the dielectric material, over the nitride layer and between the dummy gates;
removing the dummy gates by implementing an etching process, wherein the nitride layer entirely covers said dielectric material of said first gap filling layer between the dummy gates during said removing; and
forming replacement gates in regions of the device structure previously occupied by the dummy gates.

18. The method of claim 17, wherein the forming replacement gates further comprises removing the nitride layer.

19. The method of claim 17, wherein the method further comprises:
completing the formation of the semiconductor device such that at least a portion of the nitride layer remains in the device.

20. The method of claim 17, wherein the aspect ratio is between 6 and 10.
